(19) United States
(12) Patent Application Publication
(10) Pub. No.: US 2023/0311342 A1
(43) Pub. Date: Oct. 5, 2023

(54) SUBSTRATE HOLDING HAND AND SUBSTRATE CONVEYING ROBOT

(71) Applicant: KAWASAKI JUKOGYO KABUSHIKI KAISHA, Kobe-shi, Hyogo (JP)

(72) Inventor: Ippei SHIMIZU, Kobe-shi (JP)

(73) Assignee: KAWASAKI JUKOGYO KABUSHIKI KAISHA, Kobe-shi, Hyogo (JP)

(21) Appl. No.: 18/024,536

(22) PCT Filed: Nov. 2, 2020
(86) PCT No.: PCT/JP2020/041025

§ 371 Date: Mar. 3, 2023

(30) Foreign Application Priority Data
Sep. 3, 2020 (JP) 2020-148490

(51) Int. Cl. B25J 15/00; B25J 11/00

(52) U.S. Cl. CPC B25J 15/009; B25J 15/0014; B25J 11/0095

(57) ABSTRACT

A substrate holding hand includes a blade including a support to support a substrate, a movable support unit that moves back and forth to support the substrate, a movable pressing unit that moves back and forth to press the substrate, and a positioner to position the movable support unit and the movable pressing unit in common.

### TECHNICAL FIELD

The present invention relates to a substrate holding hand and a substrate conveying robot, and relates to a substrate holding hand and a substrate conveying robot each including a movable support unit and a movable pressing unit.

### BACKGROUND ART

Conventionally, a substrate holding hand including a movable support unit and a movable pressing unit is known. Such a hand is disclosed in Japanese Patent Laid-Open No. 2013-069914, for example.

Japanese Patent Laid-Open No. 2013-069914 discloses a substrate conveying hand (substrate holding hand) to convey a substrate. This substrate conveying hand includes a movable support unit including a base end side support that moves back and forth to support the substrate, and a movable pressing unit including a pressing portion that moves back and forth to press the substrate.

### PRIOR ART

### Patent Document

Patent Document 1: Japanese Patent Laid-Open No. 2013-069914

### SUMMARY OF THE INVENTION

### Problems to be Solved by the Invention

Although not described in Japanese Patent Laid-Open No. 2013-069914, in a conventional substrate conveying hand as described in Japanese Patent Laid-Open No. 2013-069914, a movable support unit and a movable pressing unit are separately positioned. In this case, separate positioners are required for the movable support unit and the movable pressing unit, and it is difficult to simplify the structure of the positioners. Furthermore, positioning of the movable support unit and the movable pressing unit is burdensome, and thus it is also difficult to easily assemble the substrate conveying hand (substrate holding hand).

The present invention aims to provide a substrate holding hand allowing the structure of a positioner to be simplified and capable of being easily assembled, and a substrate conveying robot including the substrate holding hand.

### Means for Solving the Problems

A substrate holding hand according to a first aspect of the present invention includes a blade including a support to support a substrate, a movable support unit that moves back and forth to support the substrate, a movable pressing unit that moves back and forth to press the substrate, and a positioner to position the movable support unit and the movable pressing unit in common.

A substrate conveying robot according to a second aspect of the present invention includes a substrate holding hand and an arm to move the substrate holding hand. The substrate holding hand includes a blade including a support to support a substrate, a movable support unit that moves back and forth to support the substrate, a movable pressing unit that moves back and forth to press the substrate, and a positioner to position the movable support unit and the movable pressing unit in common.

### Effect of the Invention

According to the present invention, as described above, the positioner is provided to position the movable support unit and the movable pressing unit in common such that it is possible to simplify the structure of the positioner, and it is possible to save time and effort in positioning the movable support unit and the movable pressing unit as compared with a case in which the movable support unit and the movable pressing unit are separately positioned. Thus, it is possible to easily assemble the substrate holding hand. Furthermore, even when the movable support unit and the movable pressing unit are removed for maintenance of the substrate holding hand, the movable support unit and the movable pressing unit can be easily reattached (assembled), and thus the substrate holding hand can be easily maintained.

### BRIEF DESCRIPTION OF THE DRAWINGS

FIG. 1 is a diagram showing the configuration of a substrate conveying robot according to an embodiment of the present invention.

FIG. 2 is a perspective view showing the configuration of a substrate holding hand according to the embodiment of the present invention.

FIG. 3 is a plan view showing the configuration of the substrate holding hand according to the embodiment of the present invention.

FIG. 4 is a partially enlarged view of a positioner and a positioned portion of the substrate holding hand shown in FIG. 3.

FIG. 5 is an exploded perspective view showing a movable support unit, a first movable pressing unit, a second movable pressing unit, and the positioner of the substrate holding hand according to the embodiment of the present invention.

FIG. 6 is a perspective view showing the movable support unit, the first movable pressing unit, the second movable pressing unit, and the positioner of the substrate holding hand according to the embodiment of the present invention.

### MODES FOR CARRYING OUT THE INVENTION

An embodiment embodying the present invention is hereinafter described on the basis of the drawings.

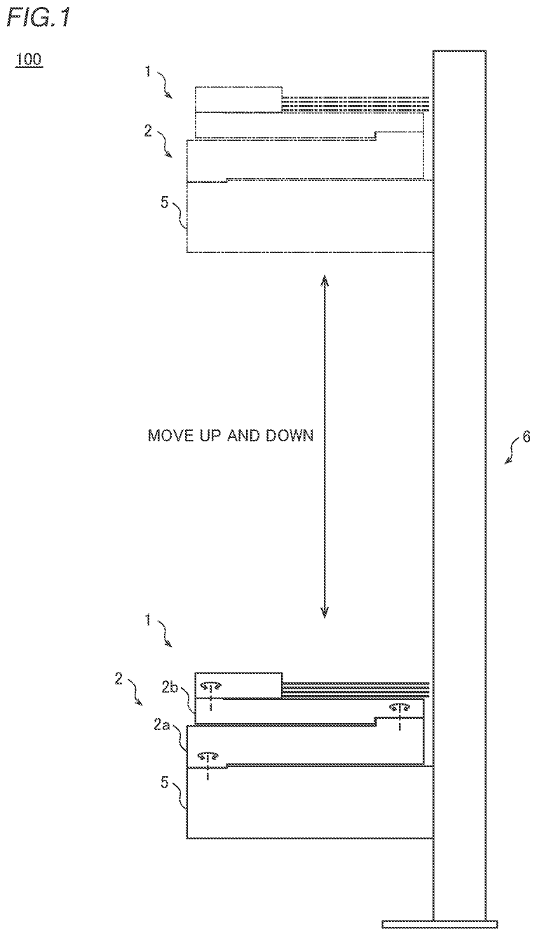

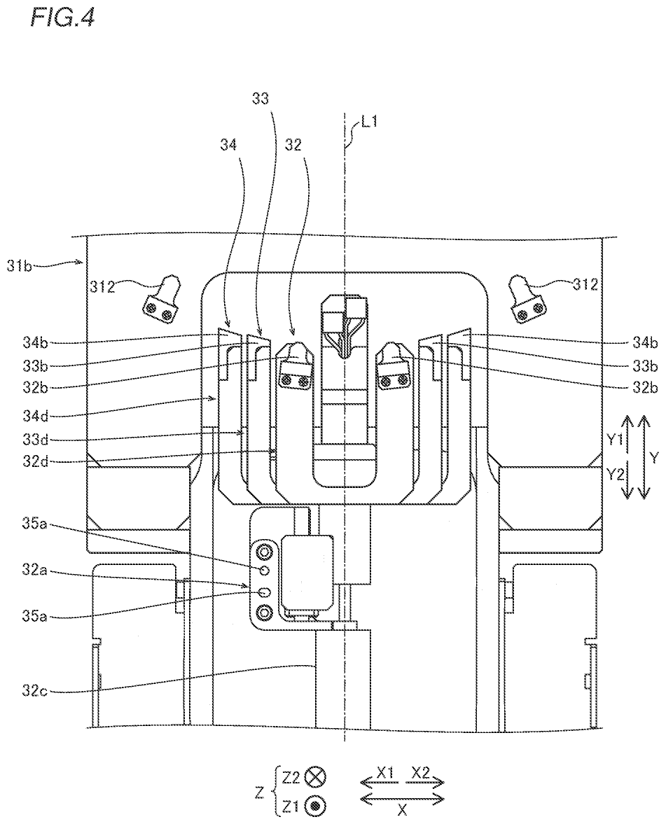

The configuration of a substrate conveying robot 100 according to this embodiment is now described with reference to FIGS. 1 to 6.

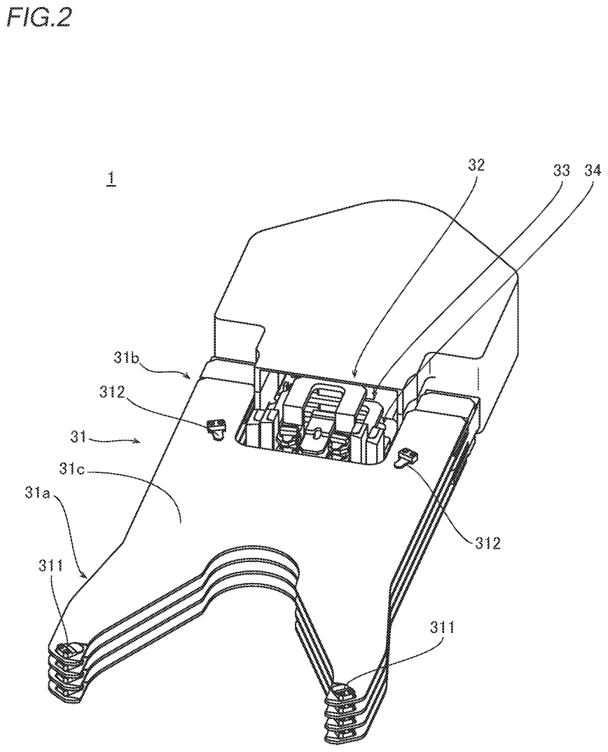

As shown in FIG. 1, the substrate conveying robot 100 includes a substrate holding hand 1 and an arm 2 that moves the substrate holding hand 1. As shown in FIGS. 2 to 6, the substrate holding hand 1 includes blades 31 including supports 311 and 312 to support substrates (semiconductor wafers) W, a movable support unit 32 that moves back and forth to support the substrates W, movable pressing units 33 and 34 that move back and forth to press the substrates W, and a positioner 35 to position the movable support unit 32 and the movable pressing units 33 and 34 in common.

According to this embodiment, as described above, the positioner 35 is provided to position the movable support unit 32 and the movable pressing units 33 and 34 in common such that it is possible to simplify the structure of the positioner 35, and it is possible to save time and effort in positioning the movable support unit 32 and the movable pressing units 33 and 34 as compared with a case in which the movable support unit 32 and the movable pressing units 33 and 34 are separately positioned. Thus, it is possible to easily assemble the substrate holding hand 1. Furthermore, even when the movable support unit 32 and the movable pressing units 33 and 34 are removed for maintenance of the substrate holding hand 1, the movable support unit 32 and the movable pressing units 33 and 34 can be easily attached (assembled), and thus the substrate holding hand 1 can be easily maintained.

The substrate holding hand 1 includes a plurality of (four) blades 31, the movable support unit 32, the movable pressing units 33 and 34, and the positioner 35, as shown in FIGS. 2 to 6.

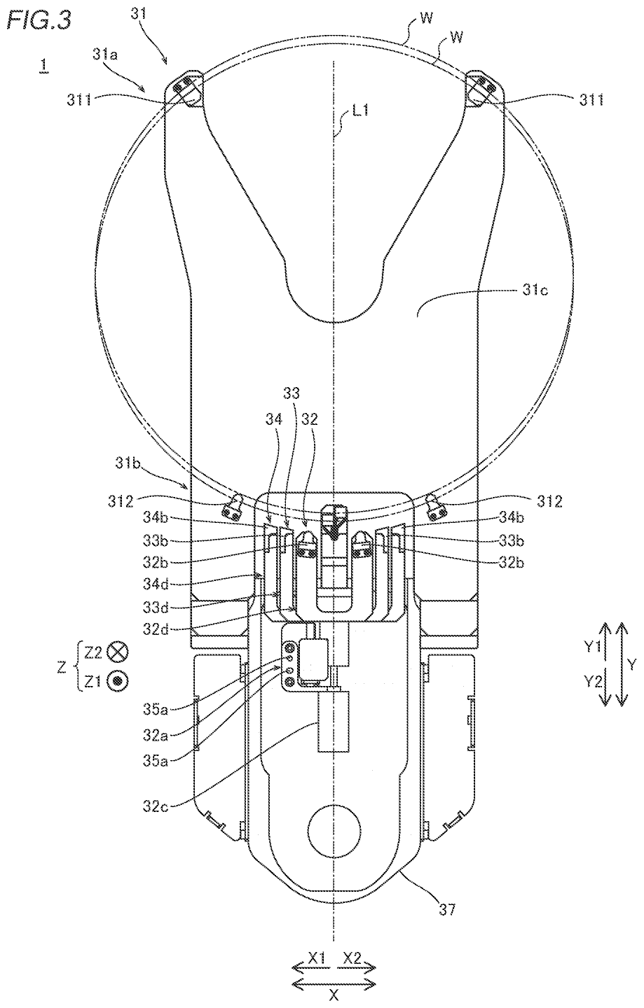

As shown in FIGS. 3 to 6, the positioner 35 includes positioning pins 35a. Each of the movable support unit 32 and the movable pressing units 33 and 34 includes a positioned portion including pin insertion holes into which the positioning pins 35a can be inserted along the positioning pins 35a. Specifically, the movable support unit 32 includes a positioned portion 32a including pin insertion holes 321 and 322 into which the positioning pins 35a can be inserted along the positioning pins 35a. The movable pressing unit 33 includes a positioned portion 33a including pin insertion holes 331 and 332 into which the positioning pins 35a can be inserted along the positioning pins 35a. The movable pressing unit 34 includes a positioned portion 34a including pin insertion holes 341 and 342 into which the positioning pins 35a can be inserted along the positioning pins 35a.

The positioning pins 35a extend in a direction (Z direction) perpendicular to the main surfaces 31c of the blades 31. The positioning pins 35a are inserted into the pin insertion holes 321, 322, 331, 332, 341, and 342 of the positioned portions 32a, 33a, and 34a while the movable support unit 32 and the movable pressing units 33 and 34 are aligned in the direction (Z direction) perpendicular to the main surfaces 31c of the blades 31 such that the movable support unit 32 and the movable pressing units 33 and 34 are positioned in common by the positioning pins 35a.

The movable support unit 32 includes support members 32b to support the substrates W. The movable pressing units 33 and 34 include pressing members 33b and 34b to press the substrates W, respectively. As viewed in the direction (Z direction) perpendicular to the main surfaces 31c of the blades 31, the support members 32b and the pressing members 33b and 34b do not overlap each other, but the positioned portion 32a of the movable support unit 32 including the pin insertion holes 321 and 322, the positioned portion 33a of the movable pressing unit 33 including the pin insertion holes 331 and 332, and the positioned portion 34a of the movable pressing unit 34 including the pin insertion holes 341 and 342 overlap each other.

The support members 32b include pairs of support members 32b. The pressing members 33b and 34b include a pair of pressing members 33b and a pair of pressing members 34b, respectively. The pairs of support members 32b, the pair of pressing members 33b, and the pair of pressing members 34b are arranged at positions symmetrical with respect to a centerline L1 extending in a direction (Y direction) in which the movable support unit 32 and the movable pressing units 33 and 34 move back and forth, as viewed in the direction (Z direction) perpendicular to the main surfaces 31c of the blades 31. The pin insertion holes 321, 322, 331, 332, 341, and 342 are arranged on one side (X1 direction side) with respect to the centerline L1, as viewed in the direction (Z direction) perpendicular to the main surfaces 31c of the blades 31.

The positioning pins 35a include a pair of positioning pins 35a. The pin insertion holes include a pair of pin insertion holes 321 and 322 (331 and 332, 341 and 342) corresponding to the pair of positioning pins 35a. One (322, 332, 342) of the pair of pin insertion holes 321 and 322 (331 and 332, 341 and 342) has an elongated hole shape. Specifically, the pin insertion hole 322 (332, 342) has an elongated hole shape having a longitudinal direction in a direction (X direction) perpendicular to the direction (Y direction) in which the movable support unit 32 and the movable pressing units 33 and 34 move back and forth, as viewed in the direction (Z direction) perpendicular to the main surfaces 31c of the blades 31. Furthermore, the pin insertion hole 321 (331, 341) has a substantially circular shape, as viewed in the direction (Z direction) perpendicular to the main surfaces 31c of the blades 31.

The substrate holding hand 1 further includes fixing members 36 to fix, in common, the movable support unit 32 and the movable pressing units 33 and 34 that have been positioned in common by the positioner 35.

The positioned portion 32a of the movable support unit 32 includes the pin insertion holes 321 and 322 and fixing member insertion holes 323 into which the fixing members 36 can be inserted. The positioned portion 33a of the movable pressing unit 33 includes the pin insertion holes 331 and 332 and fixing member insertion holes 333 into which the fixing members 36 can be inserted. The positioned portion 34a of the movable pressing unit 34 includes the pin insertion holes 341 and 342 and fixing member insertion holes 343 into which the fixing members 36 can be inserted. The pin insertion holes 321 and 322 (331 and 332, 341 and 342) and the fixing member insertion holes 323 (333, 343) of the positioned portion 32a (33a, 34a) are arranged adjacent to each other in the direction (Y direction) in which the movable support unit 32 and the movable pressing units 33 and 34 move back and forth.

As shown in FIG. 3, the supports 311 and 312 include front supports 311 on the tip end 31a side (Y1 direction side) of each blade 31 and rear supports 312 on the base end 31b side (Y2 direction side) of each blade 31. The movable support unit 32 supports the substrates W together with the front supports 311. The movable pressing units 33 and 34 include the first movable pressing unit 33 to press the substrates W supported by the front supports 311 and the movable support unit 32, and the second movable pressing unit 34 to press the substrates W supported by the front supports 311 and the rear supports 312.

The front supports 311 and the movable support unit 32 support the processed (washed) substrates W. The front supports 311 and the rear supports 312 support the substrates W prior to processing (washing). The first movable pressing unit 33 presses the processed (washed) substrates W supported by the front supports 311 and the movable support unit 32. The second movable pressing unit 34 presses the substrates W prior to processing (washing) supported by the front supports 311 and the rear supports 312. The first movable pressing unit 33 and the second movable pressing unit 34 are used properly for the substrates W prior to processing (washing) and the processed (washed) substrates W.

As shown in FIG. 1, the arm 2 is a horizontal articulated robot arm. The arm 2 includes a first arm 2a and a second arm 2b. The first arm 2a is rotatable with respect to a base 5, which is described below, with a first end as the center of rotation. Specifically, the first end of the first arm 2a is rotatably connected to the base 5 via a first joint. The second arm 2b is rotatable with respect to the first arm 2a with a first end as the center of rotation. Specifically, the first end of the second arm 2b is rotatably connected to a second end of the first arm 2a via a second joint. The substrate holding hand 1 is rotatably connected to a second end of the second arm 2b via a third joint. A drive mechanism including a servomotor corresponding to a drive source for rotary drive, a rotational position sensor that detects the rotational position of an output shaft of the servomotor, and a power transmission mechanism that transmits the output of the servomotor to the joint is provided at each of the first joint, the second joint, and the third joint.

The substrate conveying robot 100 further includes the base 5 to which the arm 2 is attached, and an arm elevating mechanism 6 to which the base 5 is attached. A first end of the base 5 is connected to the first end of the first arm 2a, and a second end of the base 5 is connected to the arm elevating mechanism 6. The arm elevating mechanism 6 moves the arm 2 up and down by moving the base 5 up and down. The arm elevating mechanism 6 includes a servomotor corresponding to a drive source for up-down drive, a rotational position sensor that detects the rotational position of an output shaft of the servomotor, and a power transmission mechanism that transmits the output of the servomotor to the base 5 (arm 2).

As shown in FIG. 2, the substrate holding hand 1 includes the plurality of (four) blades 31. That is, the substrate holding hand 1 can convey (hold) a plurality of (four) substrates W.

As shown in FIGS. 3 to 6, the substrate holding hand 1 further includes a frame 37. The frame 37 is a support that supports the blades 31. On the inside of the frame 37, portions (portions on the Y2 direction side) of the movable support unit 32, the first movable pressing unit 33, and the second movable pressing unit 34 are arranged. The positioner 35 is provided at the bottom of the frame 37. The positioning pins 35a of the positioner 35 protrude upward (in a Z1 direction) perpendicular to the main surfaces 31c of the blades 31 from the bottom of the frame 37. The bottom of the frame 37 includes fastening holes (screw holes) 36a to which the tip ends of the fixing members (fastening members) 36 extending in the Z direction are fastened. The positioning pins 35a and the fastening holes 36a are arranged adjacent to each other in the direction (Y direction) in which the movable support unit 32 and the movable pressing units 33 and 34 move back and forth.

As shown in FIG. 2, the blades 31 are thin support plates that support the substrates W. Each of the blades 31 has a shape in which the tip end 31a side is bifurcated. In the blade 31, a pair of front supports 311 are distributed to the bifurcated portions. The pair of front supports 311 each have a plurality of (two) support surfaces at different heights. A pair of rear supports 312 each have a support surface at a height substantially the same as the heights of the support surfaces of the pair of front supports 311 on the lower side (Z2 direction side). The “height” refers to a distance from the main surfaces 31c of the blades 31 in the direction (Z direction) perpendicular to the main surfaces 31c of the blades 31.

The pair of front supports 311 and the pair of rear supports 312 are provided on the main surface 31c of each blade 31. The support surfaces of the pair of front supports 311 and the pair of rear supports 312 support the rear surface (the surface on the Z2 direction side) of the outer peripheral edge of a substantially circular substrate W from below.

As shown in FIGS. 2 to 6, the substrate holding hand 1 includes the movable support unit 32, the first movable pressing unit 33, and the second movable pressing unit 34. The movable support unit 32 includes the support members 32b, an air cylinder 32c corresponding to an actuator that moves the support members 32b back and forth in the Y direction, and a mount 32d to which the support members 32b are mounted and that connects the support members 32b to the air cylinder 32c. In the movable support unit 32, the support members 32b can be moved forward in the Y1 direction via the mount 32d by the air cylinder 32c to be placed at support positions at which the support members 32b support the substrates W. Furthermore, in the movable support unit 32, the support members 32b can be moved backward in the Y2 direction via the mount 32d by the air cylinder 32c to be placed at retracted positions at which the support members 32b do not support the substrates W.

The support members 32b include the pairs of support members 32b aligned in the X direction. The pairs of support members 32b corresponding to the number (four sets) of blades 31 are aligned in the direction (Z direction) perpendicular to the main surfaces 31c of the blades 31. The pairs of support members 32b have support surfaces at heights substantially the same as the heights of the upper (Z1 direction side) support surfaces of pairs of front supports 311. Each support surface of the pairs of support members 32b supports the rear surface (the surface on the Z2 direction side) of the outer peripheral edge of the substantially circular substrate W from below. The air cylinder 32c includes a rod 324 that moves back and forth in the Y direction. The rod 324 of the air cylinder 32c is connected to the base end of the mount 32d. The mount 32d has a shape in which the tip end side (Y1 direction side) is bifurcated. In the mount 32d, the pairs of support members 32b are distributed to the bifurcated portions.

The first movable pressing unit 33 includes the pressing members 33b, an air cylinder 33c corresponding to an actuator that moves the pressing members 33b back and forth in the Y direction, and a mount 33d to which the pressing members 33b are mounted and that connects the pressing members 33b to the air cylinder 33c. In the first movable pressing unit 33, the pressing members 33b can be moved forward in the Y1 direction via the mount 33d by the air cylinder 33c to press the substrates W. Furthermore, in the first movable pressing unit 33, the pressing members 33b can be moved backward in the Y2 direction via the mount 33d by the air cylinder 33c to be placed at retracted positions at which the pressing members 33b do not press the substrates W.

The pressing members 33b include the pair of pressing members 33b aligned in the X direction. The pair of pressing members 33b extend in the direction (Z direction) perpendicular to the main surfaces 31c of the blades 31 so as to be able to collectively press the plurality of substrates W supported by the plurality of blades 31. The air cylinder 33c includes a rod 334 that moves back and forth in the Y direction. The rod 334 of the air cylinder 33c is connected to the base end of the mount 33d. The mount 33d has a shape in which the tip end side (Y1 direction side) is bifurcated. In the mount 33d, the pair of pressing members 33b are distributed to the bifurcated portions.

The second movable pressing unit 34 includes the pressing members 34b, an air cylinder 34c corresponding to an actuator that moves the pressing members 34b back and forth in the Y direction, and a mount 34d to which the pressing members 34b are mounted and that connects the pressing members 34b to the air cylinder 34c. In the second movable pressing unit 34, the pressing members 34b can be moved forward in the Y1 direction via the mount 34d by the air cylinder 34c to press the substrates W. Furthermore, in the second movable pressing unit 34, the pressing members 34b can be moved backward in the Y2 direction via the mount 34d by the air cylinder 34c to be placed at retracted positions at which the pressing members 34b do not press the substrates W.

The pressing members 34b include the pair of pressing members 34b aligned in the X direction. The pair of pressing members 33b extend in the direction (Z direction) perpendicular to the main surfaces 31c of the blades 31 so as to be able to collectively press the plurality of substrates W supported by the plurality of blades 31. The air cylinder 34c includes a rod 344 that moves back and forth in the Y direction. The rod 344 of the air cylinder 34c is connected to the base end of the mount 34d. The mount 34d has a shape in which the tip end side (Y1 direction side) is bifurcated. In the mount 34d, the pair of pressing members 34b are distributed to the bifurcated portions.

The support members 32b of the movable support unit 32, the pressing members 33b of the first movable pressing unit 33, and the pressing members 34b of the second movable pressing unit 34 are arranged from the inside (the side closer to the centerline L1) toward the outside (the side farther from the centerline L1) in the X direction in this order. The support members 32b of the movable support unit 32, the pressing members 33b of the first movable pressing unit 33, and the pressing members 34b of the second movable pressing unit 34 do not overlap each other, as viewed in the direction (Z direction) perpendicular to the main surfaces 31c of the blades 31.

The air cylinder 32c of the movable support unit 32, the air cylinder 33c of the first movable pressing unit 33, and the air cylinder 34c of the second movable pressing unit 34 are aligned in the direction (Z direction) perpendicular to the main surfaces 31c of the blades 31. Specifically, the air cylinder 32c of the movable support unit 32, the air cylinder 33c of the first movable pressing unit 33, and the air cylinder 34c of the second movable pressing unit 34 overlap each other, as viewed in the direction (Z direction) perpendicular to the main surfaces 31c of the blades 31.

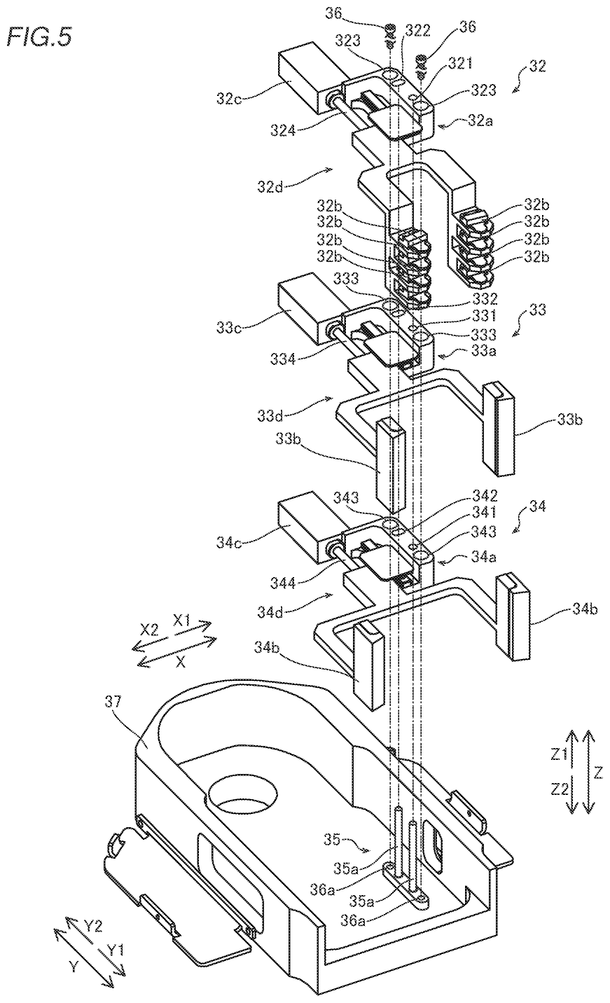

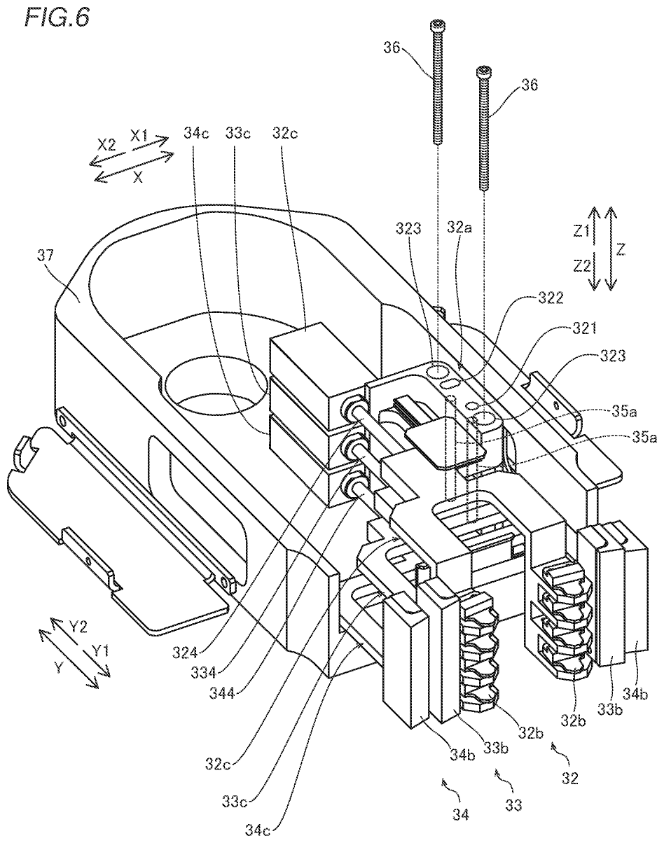

A method for attaching the movable support unit 32, the first movable pressing unit 33, and the second movable pressing unit 34 is described with reference to FIGS. 5 and 6.

As shown in FIG. 5, first, the second movable pressing unit 34 arranged on the lowermost side (the Z2 direction side, the bottom side of the frame 37) is positioned with respect to the frame 37 by the positioner 35. Specifically, the second movable pressing unit 34 is moved from the upper side (Z1 direction side) toward the lower side (Z2 direction side). Thus, the positioning pins 35a of the positioner 35 are inserted from the lower side (Z2 direction side) toward the upper side (Z1 direction side) into the pin insertion holes 341 and 342 of the positioned portion 34a of the second movable pressing unit 34. Consequently, the positioning pins 35a of the positioner 35 restrict movement of the second movable pressing unit 34 in the XY directions, and thus the second movable pressing unit 34 is positioned with respect to the frame 37. When the second movable pressing unit 34 is positioned, the positioning pins 35a protrude (expose) upward (in the Z1 direction) from the pin insertion holes 341 and 342 of the positioned portion 34a of the second movable pressing unit 34.

Then, the first movable pressing unit 33 arranged in the middle is positioned with respect to the frame 37 by the common positioner 35. Specifically, the first movable pressing unit 33 is moved from the upper side (Z1 direction side) toward the lower side (Z2 direction side) and placed on the positioned (already arranged) second movable pressing unit 34. At this time, the first movable pressing unit 33 is moved until the lower surface of the positioned portion 33a of the first movable pressing unit 33 contacts the upper surface of the positioned portion 34a of the second movable pressing unit 34. Thus, the positioning pins 35a protruding upward (in the Z1 direction) from the pin insertion holes 341 and 342 are inserted into the pin insertion holes 331 and 332 of the positioned portion 33a of the first movable pressing unit 33 from the lower side (Z2 direction side) toward the upper side (Z1 direction side). Consequently, the positioning pins 35a of the positioner 35 restrict movement of the first movable pressing unit 33 in the XY directions, and thus the first movable pressing unit 33 is positioned with respect to the frame 37. When the first movable pressing unit 33 is positioned, the positioning pins 35a protrude (expose) upward (in the Z1 direction) from the pin insertion holes 331 and 332 of the positioned portion 33a of the first movable pressing unit 33.

Then, the movable support unit 32 arranged on the uppermost side (Z1 direction side) is positioned with respect to the frame 37 by the common positioner 35. Specifically, the movable support unit 32 is moved from the upper side (Z1 direction side) toward the lower side (Z2 direction side) and placed on the positioned (already arranged) first movable pressing unit 33. At this time, the movable support unit 32 is moved until the lower surface of the positioned portion 32a of the movable support unit 32 contacts the upper surface of the positioned portion 33a of the first movable pressing unit 33. Thus, the positioning pins 35a protruding upward (in the Z1 direction) from the pin insertion holes 331 and 332 are inserted into the pin insertion holes 321 and 322 of the positioned portion 32a of the movable support unit 32 from the lower side (Z2 direction side) toward the upper side (Z1 direction side). Consequently, the positioning pins 35a of the positioner 35 restrict movement of the movable support unit 32 in the XY directions, and thus the movable support unit 32 is positioned with respect to the frame 37. When the movable support unit 32 is positioned, the positioning pins 35a do not protrude upward (in the Z1 direction) from the pin insertion holes 321 and 322 of the positioned portion 32a of the movable support unit 32.

Then, as shown in FIG. 6, the movable support unit 32, the first movable pressing unit 33, and the second movable pressing unit 34, all of which have been positioned by the common positioner 35, are fixed to the frame 37 by the common fixing members 36. Specifically, the fixing members 36 are inserted from the upper side (Z1 direction side) toward the lower side (Z2 direction side) into the fixing member inserting holes 323 of the positioned portion 32a, the fixing member inserting holes 333 of the positioned portion 33a, and the fixing member inserting holes 343 of the positioned portion 34a aligned in an upward-downward direction (Z direction). Then, the tip ends of the fixing members 36 inserted in the upward-downward direction through the three fixing member insertion holes 323, 333, and 343 are fastened to the fastening holes 36a (see FIG. 5). Consequently, the movable support unit 32, the first movable pressing unit 33, and the second movable pressing unit 34 are fixed to the frame 37 by the common fixing members 36 at once.

### Advantages of this Embodiment

According to this embodiment, the following advantages are achieved.

According to this embodiment, as described above, the positioner 35 is provided to position the movable support unit 32 and the movable pressing units 33 and 34 in common such that it is possible to simplify the structure of the positioner 35, and it is possible to save time and effort in positioning the movable support unit 32 and the movable pressing units 33 and 34 as compared with a case in which the movable support unit 32 and the movable pressing units 33 and 34 are separately positioned. Thus, it is possible to easily assemble the substrate holding hand 1. Furthermore, even when the movable support unit 32 and the movable pressing units 33 and 34 are removed for maintenance of the substrate holding hand 1, the movable support unit 32 and the movable pressing units 33 and 34 can be easily reattached (assembled), and thus the substrate holding hand 1 can be easily maintained.

According to this embodiment, as described above, the positioner 35 includes the positioning pins 35a. Furthermore, the movable support unit 32, the movable pressing unit 33, and the movable pressing unit 34 include the positioned portion 32a including the pin insertion holes 321 and 322 that allow the positioning pins 35a to be inserted thereinto along the positioning pins 35a, the positioned portion 33a including the pin insertion holes 331 and 332 that allow the positioning pins 35a to be inserted thereinto along the positioning pins 35a, and the positioned portion 34a including the pin insertion holes 341 and 342 that allow the positioning pins 35a to be inserted thereinto along the positioning pins 35a, respectively. Accordingly, the movable support unit 32 and the movable pressing units 33 and 34 can be positioned simply by inserting the positioning pins 35a of the positioner 35 into the pin insertion holes 321, 322, 331, 332, 341, and 342 of the positioned portions 32a, 33a, and 34a, and thus the substrate holding hand 1 can be more easily assembled.

According to this embodiment, as described above, the positioning pins 35a extend in the direction perpendicular to the main surfaces 31c of the blades 31. Furthermore, the movable support unit 32 and the movable pressing units 33 and 34 are positioned in common by the positioning pins 35a by inserting the positioning pins 35a into the pin insertion holes 321, 322, 331, 332, 341, and 342 of the positioned portions 32a, 33a, and 34a while the movable support unit 32 and the movable pressing units 33 and 34 are aligned in the direction perpendicular to the main surfaces 31c of the blades 31. Accordingly, the movable support unit 32 and the movable pressing units 33 and 34 can be positioned (assembled) from the direction perpendicular to the main surfaces 31c of the blades 31, in which there are relatively few structures, and thus the substrate holding hand 1 can be still more easily assembled. Furthermore, the movable support unit 32 and the movable pressing units 33 and 34 can be aligned in the direction perpendicular to the main surfaces 31c of the blades 31, and thus the movable support unit 32 and the movable pressing units 33 and 34 can be compactly arranged in the direction parallel to the main surfaces 31c of the movable support units 31 and perpendicular to the direction in which the movable support unit 32 and the movable pressing units 33 and 34 move back and forth.

According to this embodiment, as described above, the movable support unit 32 includes the support members 32b to support the substrates W. The movable pressing units 33 and 34 include the pressing members 33b and 34b to press the substrates W, respectively. As viewed in the direction perpendicular to the main surfaces 31c of the blades 31, the support members 32b and the pressing members 33b and 34b are located so as not to overlap each other, and the positioned portion 32a, 33a, and 34a of the movable support unit 32 including the pin insertion holes 321, 322, 331, 332, 341, and 342 and the positioned portions 32a, 33a, and 34a of the movable pressing units 33 and 34 including the pin insertion holes 321, 322, 331, 332, 341, and 342 are located so as to overlap each other. Accordingly, the positions of the support members 32b of the movable support unit 32 and the positions of the pressing members 33b and 34b of the movable pressing units 33 and 34 can be shifted from each other, and thus when the movable support unit 32 and the movable pressing units 33 and 34 are positioned (assembled), the support members 32b of the movable support unit 32 and the pressing members 33b and 34b of the movable pressing units 33 and 34 do not interfere with each other. Consequently, the movable support unit 32 and the movable pressing units 33 and 34 can be easily arranged, and thus the movable support unit 32 and the movable pressing units 33 and 34 can be easily positioned (assembled). Furthermore, the positions of the support members 32b of the movable support unit 32 and the positions of the pressing members 33b and 34b of the movable pressing units 33 and 34 can be shifted from each other, and thus the substrates W can be supported and pressed by the support members 32b of the movable support unit 32 and the pressing members 33b and 34b of the movable pressing units 33 and 34 at the same height.

According to this embodiment, as described above, the support members 32b include the pairs of support members 32b. The pressing members 33b and 34b include the pair of pressing members 33b and the pair of pressing members 34b. The pairs of support members 32b, the pair of pressing members 33b, and the pair of pressing members 34b are arranged at the positions symmetrical with respect to the centerline L1 extending in the direction in which the movable support unit 32 and the movable pressing units 33 and 34 move back and forth, as viewed in the direction perpendicular to the main surfaces 31c of the blades 31. The pin insertion holes 321, 322, 331, 332, 341, and 342 are arranged on one side with respect to the centerline L1, as viewed in the direction perpendicular to the main surfaces 31c of the blades 31. Accordingly, the pairs of support members 32b of the movable support unit 32 and the pair of pressing members 33b and the pair of pressing members 34b of the movable pressing units 33 and 34 can be arranged at appropriate positions, and when drives (air cylinders 32c, 33c, and 34c) of the movable support unit 32 and the movable pressing units 33 and 34 are arranged on the centerline L1, the pin insertion holes 321, 322, 331, 332, 341, and 342 of the positioned portions 32a, 33a, and 34a can be arranged at appropriate positions while avoiding the drives.

According to this embodiment, as described above, the positioning pins 35a include the pair of positioning pins 35a. The pin insertion holes 321, 322, 331, 332, 341, and 342 include the pair of pin insertion holes 321 and 322, the pair of pin insertion holes 331 and 332, and the pair of pin insertion holes 341 and 342 corresponding to the pair of positioning pins 35a. One of the pair of pin insertion holes 321 and 322, one of the pair of pin insertion holes 331 and 332, and one of the pair of pin insertion holes 341 and 342 have an elongated hole shape. Accordingly, as compared with a case in which both of the pair of pin insertion holes 321 and 322, both of the pair of pin insertion holes 331 and 332, and both of the pair of pin insertion holes 341 and 342 are circular, the pair of positioning pins 35a can be easily inserted into the pair of pin insertion holes 321 and 322, the pair of pin insertion holes 331 and 332, and the pair of pin insertion holes 341 and 342, and thus the movable support unit 32 and the movable pressing units 33 and 34 can be easily positioned (assembled).

According to this embodiment, as described above, the substrate holding hand 1 further includes the fixing members 36 to fix, in common, the movable support unit 32 and the movable pressing units 33 and 34 that have been positioned in common by the positioner 35. Accordingly, it is possible to save time and effort in fixing the movable support unit 32 and the movable pressing units 33 and 34 as compared with a case in which the movable support unit 32 and the movable pressing units 33 and 34 are separately fixed, and thus the substrate holding hand 1 can be more easily assembled. Furthermore, as compared with a case in which the movable support unit 32 and the movable pressing units 33 and 34 are separately fixed, the number of fixing members 36 can be reduced.

According to this embodiment, as described above, the positioner 35 includes the positioning pins 35a. The movable support unit 32 and the movable pressing units 33 and 34 include the positioned portions 32a, 33a, and 34a including the pin insertion holes 321, 322, 331, 332, 341, and 342 that allow the positioning pins 35a to be inserted thereinto along the positioning pins 35a, and the fixing member insertion holes 323, 333, and 343 that allow the fixing members 36 to be inserted thereinto, respectively. The pin insertion holes 321, 322, 331, 332, 341, and 342 and the fixing member insertion holes 323, 333, and 343 of the positioned portions 32a, 33a, and 34a are arranged adjacent to each other in the direction in which the movable support unit 32 and the movable pressing units 33 and 34 move back and forth. Accordingly, the pin insertion holes 321, 322, 331, 332, 341, and 342 and the fixing member insertion holes 323, 333, and 343 of the positioned portions 32a, 33a, and 34a can be compactly arranged in the direction parallel to the main surfaces 31c of the blades 31 and perpendicular to the direction in which the movable support unit 32 and the movable pressing units 33 and 34 move back and forth, and thus the positioned portions 32a, 33a, and 34a can be made compact in the direction parallel to the main surfaces 31c of the blades 31 and perpendicular to the direction in which the movable support unit 32 and the movable pressing units 33 and 34 move back and forth.

According to this embodiment, as described above, the supports 311 and 312 include the front supports 311 on the tip end 31a side of each blade 31 and the rear supports 312 on the base end 31b side of each blade 31. The movable support unit 32 supports the substrates W together with the front supports 311. The movable pressing units 33 and 34 include the first movable pressing unit 33 to press the substrates W supported by the front supports 311 and the movable support unit 32, and the second movable pressing unit 34 to press the substrates W supported by the front supports 311 and the rear supports 312. Accordingly, two (two types of) substrates W can be held by one blade 31. Furthermore, even when the substrate holding hand 1 includes three units, which are the movable support unit 32, the first movable pressing unit 33, and the second movable pressing unit 34, the common positioner can position the three unit in common. Consequently, it is possible to save time and effort in positioning the movable support unit 32, the first movable pressing unit 33, and the second movable pressing unit 34, and thus it is possible to easily assemble the substrate holding hand 1.

### MODIFIED EXAMPLES

The embodiment disclosed this time must be considered as illustrative in all points and not restrictive. The scope of the present invention is not shown by the above description of the embodiment but by the scope of claims for patent, and all modifications (modified examples) within the meaning and scope equivalent to the scope of claims for patent are further included.

For example, while the example in which the arm is a horizontal articulated robot arm has been shown in the aforementioned embodiment, the present invention is not limited to this. For example, the arm may be an arm other than a horizontal articulated robot arm, such as a vertical articulated robot arm.

While the example in which the substrate holding hand includes a plurality of blades has been shown in the aforementioned embodiment, the present invention is not limited to this. For example, the substrate holding hand may include one blade.

While the example in which the substrate holding hand includes four blades has been shown in the aforementioned embodiment, the present invention is not limited to this. For example, the substrate holding hand may include a plurality of blades other than four.

While the example in which each of the blades has a bifurcated shape has been shown in the aforementioned embodiment, the present invention is not limited to this. For example, each of the blades may have a shape other than a bifurcated shape.

While the example in which each of the blades can support two substrates at different heights has been shown in the aforementioned embodiment, the present invention is not limited to this. For example, each of the blades may be able to support only one substrate (able to support a substrate at only one height).

While the example in which the movable support unit includes pairs of support members has been shown in the aforementioned embodiment, the present invention is not limited to this. For example, the movable support unit may include one support member.

While the example in which two pressing units, which are the first movable pressing unit and the second movable pressing unit, are provided has been shown in the aforementioned embodiment, the present invention is not limited to this. For example, only one movable pressing unit may be provided.

While the example in which each of the movable pressing units includes a pair of pressing members has been shown in the aforementioned embodiment, the present invention is not limited to this. For example, each of the movable pressing units may include one pressing member.

While the example in which the positioner includes the positioning pins has been shown in the aforementioned embodiment, the present invention is not limited to this. For example, the positioner may include a positioning structure such as a positioning wall other than the positioning pins. Alternatively, the positioner may perform positioning by combining a plurality of types of positioning structures such as the positioning pins and the positioning wall.

While the example in which the positioning pins extend in the direction perpendicular to the main surfaces of the blades has been shown in the aforementioned embodiment, the present invention is not limited to this. For example, the positioning pins may extend in a direction perpendicular to the direction perpendicular to the main surfaces of the blades.

While the example in which a pair of (two) positioning pins are provided has been shown in the aforementioned embodiment, the present invention is not limited to this. For example, one or three or more positioning pins may be provided.

While the example in which the movable support unit and the movable pressing units that have been positioned in common by the positioner are fixed by the common fixing members has been shown in the aforementioned embodiment, the present invention is not limited to this. For example, the movable support unit and the movable pressing units that have been positioned in common by the positioner may be fixed by separate fixing members.

While the example in which the second movable pressing unit, the first movable pressing unit, and the movable support unit are positioned in this order by the positioning pins of the positioner has been shown in the aforementioned embodiment, the present invention is not limited to this. In the present invention, either the movable pressing units or the movable support unit may be positioned first.

### DESCRIPTION OF REFERENCE NUMERALS

1: substrate holding hand
2: arm
31: blade
31a: tip end
31b: base end
31c: main surface
32: movable support unit
32a, 33a, 34a: positioned portion
32b: support member
33: first movable pressing unit (movable pressing unit)
33b, 34b: pressing member
34: second movable pressing unit (movable pressing unit)
35: positioner
35a: positioning pin
36: fixing member
311: front support (support)
312: rear support (support)
321, 322, 331, 332, 341, 342: pin insertion hole
323, 333, 343: fixing member insertion hole
L1: centerline
W: substrate

1. A substrate holding hand comprising:
a blade including a support to support a substrate;
a movable support unit that moves back and forth to support the substrate;
a movable pressing unit that moves back and forth to press the substrate; and
a positioner to position the movable support unit and the movable pressing unit in common.

2. The substrate holding hand according to claim 1, wherein
the positioner includes a positioning pin; and
each of the movable support unit and the movable pressing unit includes a positioned portion including a pin insertion hole to allow the positioning pin to be inserted thereinto along the positioning pin.

3. The substrate holding hand according to claim 2, wherein
the positioning pin extends in a direction perpendicular to a main surface of the blade; and
the movable support unit and the movable pressing unit are positioned in common by the positioning pin by inserting the positioning pin into the pin insertion hole of the positioned portion while the movable support unit and the movable pressing unit are aligned in the direction perpendicular to the main surface of the blade.

4. The substrate holding hand according to claim 3, wherein
the movable support unit includes a support member to support the substrate;
the movable pressing unit includes a pressing member to press the substrate; and
as viewed in the direction perpendicular to the main surface of the blade, the support member and the pressing member are located so as not to overlap each other, and the positioned portion of the movable support unit including the pin insertion hole and the positioned portion of the movable pressing unit including the pin insertion hole are located so as to overlap each other.

5. The substrate holding hand according to claim 4, wherein
the support member includes a pair of support members;
the pressing member includes a pair of pressing members;
the pair of support members and the pair of pressing members are arranged at positions symmetrical with respect to a centerline extending in a direction in which the movable support unit and the movable pressing unit move back and forth, as viewed in the direction perpendicular to the main surface of the blade; and
the pin insertion holes are arranged on one side with respect to the centerline, as viewed in the direction perpendicular to the main surface of the blade.

6. The substrate holding hand according to claim 2, wherein
the positioning pin includes a pair of positioning pins;
the pin insertion hole includes a pair of pin insertion holes corresponding to the pair of positioning pins; and
one of the pair of pin insertion holes has an elongated hole shape.

7. The substrate holding hand according to claim 1, further comprising:
a fixing member to fix, in common, the movable support unit and the movable pressing unit that have been positioned in common by the positioner.

8. The substrate holding hand according to claim 7, wherein
the positioner includes a positioning pin;
each of the movable support unit and the movable pressing unit includes a positioned portion including a pin insertion hole to allow the positioning pin to be inserted thereinto along the positioning pin, and a fixing member insertion hole to allow the fixing member to be inserted thereinto; and
the pin insertion hole and the fixing member insertion hole of the positioned portion are arranged adjacent to each other in a direction in which the movable support unit and the movable pressing unit move back and forth.

9. The substrate holding hand according to claim 1, wherein
the support includes a front support on a tip end side of the blade and a rear support on a base end side of the blade;
the movable support unit supports the substrate together with the front support; and
the movable pressing unit includes a first movable pressing unit to press the substrate supported by the front support and the movable support unit, and a second movable pressing unit to press the substrate supported by the front support and the rear support.

10. A substrate conveying robot comprising:
a substrate holding hand; and
an arm to move the substrate holding hand; wherein the substrate holding hand includes:
a blade including a support to support a substrate;
a movable support unit that moves back and forth to support the substrate;
a movable pressing unit that moves back and forth to press the substrate; and
a positioner to position the movable support unit and the movable pressing unit in common.
